(19) United States
(12) Patent Application Publication
(10) Pub. No.: US 2024/0353677 A1
(43) Pub. Date: Oct. 24, 2024

(54) OPTICAL DEVICE AND IMAGING UNIT INCLUDING OPTICAL DEVICE

(71) Applicant: Murata Manufacturing Co., Ltd., Nagaokakyo-shi (JP)

(72) Inventors: Yuuki ISHII, Nagaokakyo-shi (JP); Takahide NAKADOI, Nagaokakyo-shi (JP); Noritaka KISHI, Nagaokakyo-shi (JP); Hitoshi SAKAGUCHI, Nagaokakyo-shi (JP)

(21) Appl. No.: 18/762,179

(22) Filed: Jul. 2, 2024

Related U.S. Application Data
(63) Continuation of application No. PCT/JP2022/039133, filed on Oct. 20, 2022.

(30) Foreign Application Priority Data
Feb. 25, 2022 (JP) 2022-028248

(51) Int. Cl. G02B 27/00; B06B 1/06; B60S 1/56; G02B 7/02; G03B 17/08; H04N 23/81; H10N 30/80

(52) U.S. Cl. CPC G02B 27/0006; B06B 1/06; B60S 1/56; G02B 7/02; G03B 17/08; H04N 23/81; H10N 30/802; G03B 2205/0061

(57) ABSTRACT

An optical device includes an outermost layer lens, a housing, a vibrator, an inner layer lens, a fixing portion, and a position adjustment portion. The vibrator vibrates the outermost layer lens held by the housing. The inner layer lens faces the outermost layer lens. The fixing portion fixes the inner layer lens to the housing. The position adjustment portion is provided in the fixing portion to adjust alignment of the inner layer lens with respect to the outermost layer lens. The fixing portion is connected to a portion of the housing that is a node of vibration by the vibrator.

### CROSS REFERENCE TO RELATED APPLICATIONS

This application claims the benefit of priority to Japanese Patent Application No. 2022-028248 filed on Feb. 25, 2022 and is a Continuation Application of PCT Application No. PCT/JP2022/039133 filed on Oct. 20, 2022. The entire contents of each application are hereby incorporated herein by reference.

### BACKGROUND OF THE INVENTION

### 1. Field of the Invention

The present disclosure relates to optical devices and imaging units including the optical devices.

### 2. Description of the Related Art

An imaging unit has been provided in a front portion or a rear portion of a vehicle, and images captured by the imaging unit have been used to control a safety device and perform driving support control. Since such an imaging unit is often provided outside a vehicle, foreign matters such as raindrops (water drops), mud, dust, and the like can adhere to a light-transmissive body (protective cover or lens) that covers an outer portion of the imaging unit. When foreign matters adhere to the light-transmissive body, the foreign matters are included in an image captured by the imaging unit, and a clear image is not obtained.

Therefore, in the imaging unit described in Japanese Unexamined Patent Application Publication No. 2017-170303 or the imaging unit described in U.S. Pat. No. 10,401,618, a vibrator that vibrates a light-transmissive body so as to remove foreign matters adhering to a surface of the light-transmissive body is provided.

### SUMMARY OF THE INVENTION

The imaging units described in Japanese Unexamined Patent Application Publication No. 2017-170303 and U.S. Pat. No. 10,401,618 each include an imaging element and an optical device including a light-transmissive body and a lens provided in a visual field direction of the imaging element. The optical device requires alignment adjustment between the light-transmissive body and the lens so that light taken in from the light-transmissive body is formed into an image in the imaging element through the lens. However, the imaging unit described in Japanese Unexamined Patent Application Publication No. 2017-170303 does not include a structure configured to perform alignment adjustment between the light-transmissive body and the lens, and thus the image quality of images captured by the imaging element may be deteriorated.

Therefore, example embodiments of the present invention provide optical devices each capable of removing foreign matters adhering to a light-transmissive body that covers an outer portion of the optical device and improving the image quality of images captured by an imaging element, and imaging units including the optical devices.

An optical device according to an example embodiment of the present disclosure includes a light-transmissive body, a housing, a vibrator, a first lens, a fixing portion, and a position adjustment portion. The light-transmissive body allows light having a predetermined wavelength to pass therethrough. The housing holds the light-transmissive body. The vibrator vibrates the light-transmissive body held by the housing. The first lens is provided at a position, in the housing, facing the light-transmissive body. The fixing portion fixes the first lens to the housing. The position adjustment portion is provided in the fixing portion to adjust alignment of the first lens with respect to the light-transmissive body. The fixing portion is connected to a portion of the housing that is a node of vibration by the vibrator.

An imaging unit according to an example embodiment of the present disclosure includes the optical device described above, and an imager positioned such that the light-transmissive body is provided in a visual field direction of the imaging unit.

According to example embodiments of the present disclosure, since optical devices and imaging units including the optical devices each adjust alignment of a first lens with respect to a light-transmissive body in a position adjustment portion provided in a fixing portion, foreign matters adhering to the light-transmissive body that covers an outer portion of the optical device can be removed, and the image quality of the images captured by the imaging element can be improved.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a sectional view of an optical device according to a first example embodiment of the present invention.

FIG. 2 is a schematic view for explaining a vibration mode of the optical device according to the first example embodiment of the present invention.

FIG. 3 is a half sectional view for explaining a position adjustment portion of the optical device according to the first example embodiment of the present invention.

FIGS. 4A to 4C are schematic views for explaining an alignment adjustment method in the position adjustment portion of the optical device according to the first example embodiment of the present invention.

FIGS. 5A and 5B are schematic views for explaining a fixing method of the position adjustment portion of the optical device according to the first example embodiment of the present invention.

FIG. 6 is a sectional view of an imaging unit including the optical device according to the first example embodiment of the present invention.

FIG. 7 is a half sectional view of an optical device according to a second example embodiment of the present invention.

FIGS. 8A to 8C are schematic views for explaining an adjustment method in the position adjustment portion of the optical device according to the second example embodiment of the present invention.

FIGS. 9A to 9D are schematic views for explaining another adjustment method in the position adjustment portion of the optical device according to the second example embodiment of the present invention.

FIGS. 10A to 10C are views for explaining a configuration using an outermost layer lens and a holding portion of an inner layer lens for abutting position determination in the optical device.

FIGS. 11A to 11C are views for explaining a configuration using the outermost layer lens and the inner layer lens for abutting position determination in the optical device.

FIGS. 12A to 12C are views for explaining a configuration using a vibrator and the holding portion of the inner layer lens for abutting position determination in the optical device.

FIGS. 13A to 13C are views for explaining a configuration using the vibrator and the inner layer lens for abutting position determination in the optical device.

FIG. 14 is a half sectional view of an optical device according to a third example embodiment of the present invention.

FIG. 15 is a half sectional view of an optical device according to a first modification of the third example embodiment of the present invention.

FIG. 16 is a half sectional view of an optical device according to a second modification of the third example embodiment of the present invention.

FIGS. 17A and 17B are schematic views of the inner layer lens and the fixing portion according to the second modification of the third example embodiment of the present invention.

FIG. 18 is a half sectional view of an optical device according to a fourth example embodiment of the present invention.

### DETAILED DESCRIPTION OF THE EXAMPLE EMBODIMENTS

Hereinafter, optical devices according to example embodiments and imaging units including the optical devices will be described in detail with reference to the drawings. Note that the same reference numerals in the drawings denote the same or corresponding portions. Each of the optical devices described below is applicable to a car-mounted imaging unit, for example, and can vibrate a light-transmissive body (for example, an outermost layer lens) so as to remove foreign matters adhering to a surface of the light-transmissive body. The optical device is not limited to being used for a car-mounted imaging unit. For example, the optical device can also be applied to a monitoring camera for security, an imaging unit for a drone, and the like.

### First Example Embodiment

FIG. 1 is a sectional view of an optical device 100 according to a first example embodiment. Note that X and Z directions in the figure indicate a lateral direction and a height direction of the optical device 100, respectively. The optical device 100 includes an outermost layer lens 1, a housing 2, a vibrator 3, an inner layer lens 4, a fixing portion 5, and a position adjustment portion 6.

The outermost layer lens 1 is a light-transmissive body that allows light having a predetermined wavelength (for example, a wavelength of visible light, a wavelength that can be captured by an imaging element, or the like) to pass therethrough and is, for example, a convex meniscus lens. Note that in the optical device 100, a transparent structure such as a protective cover may be used instead of the outermost layer lens 1. The protective cover is made of glass or resin such as transparent plastic.

An end portion of the outermost layer lens 1 is held by an end portion of the housing 2. The optical device 100 is provided with the vibrator 3 at a position in contact with the outermost layer lens 1 so as to vibrate the outermost layer lens 1 held by the housing 2.

The vibrator 3 has a cylindrical shape, and the inner layer lens 4 is disposed inside the cylinder. The vibrator 3 includes a connecting portion 31 that connects the vibrator 3 to the outermost layer lens 1 (the light-transmissive body) and a vibrating portion 32 provided with a piezoelectric element 7. The connecting portion 31 converts vibration of the piezoelectric element 7 and has a crank shape. On the other hand, the vibrating portion 32 vibrates together with the vibration of the piezoelectric element 7 and is thicker than the connecting portion 31 that is thin. Note that the connecting portion 31 and the vibrating portion 32 may be integrally formed or separately formed. The piezoelectric element 7 is provided on a surface of the vibrator 3 on a side opposite to a side in contact with the outermost layer lens 1. The piezoelectric element 7 has a hollow cylindrical shape and vibrates by, for example, being polarized in a thickness direction. The piezoelectric element 7 is made of PZT piezoelectric ceramics. In addition, other piezoelectric ceramics such as (K, Na)NbO₃ may be used. Moreover, a piezoelectric single crystal such as LiTaO₃ may be used.

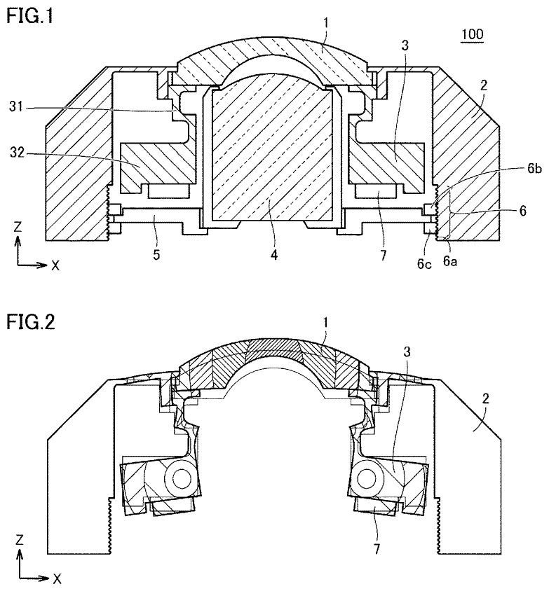

The piezoelectric element 7 having a hollow cylindrical shape vibrates in a radial direction, the vibration is converted into vibration in the Z direction (an up and down direction in the figure) in the connecting portion 31 of the vibrator 3, and the outermost layer lens 1 vibrates in the Z direction. FIG. 2 is a schematic view for explaining a vibration mode of the optical device 100 according to the first example embodiment. As understood from FIG. 2, the housing 2 transmits the vibration of the vibrator 3 to the outermost layer lens 1 when a portion (the connecting portion 31) holding the outermost layer lens 1 is elastically deformed like a plate spring, and a portion away from the outermost layer lens 1 becomes a node of the vibration. Here, a node of vibration is a portion whose amplitude is approximately equal to or less than about 1/50 of the maximum amplitude of the vibrator 3, for example. Therefore, while displacement becomes the maximum in a central portion of the outermost layer lens 1 by the vibration of the vibrator 3, displacement of a portion away from the outermost layer lens 1 becomes small. Note that in FIG. 2, the magnitudes of displacement are illustrated using the density of hatching, portions having higher densities of hatching have greater magnitudes of displacement, and displacement is large in the central portion of the outermost layer lens 1.

The optical device 100 is configured not to transmit vibration of the vibrator 3 to the inner layer lens 4 through fixing of the inner layer lens 4 to the housing 2 with the fixing portion 5 interposed therebetween in a portion of the housing 2 that is a node of vibration, specifically, near a lower end side of the housing 2, which is a side opposite to an upper end side that holds the outermost layer lens 1. Therefore, in an imaging unit using the optical device 100, deterioration of the image quality is not generated due to the vibration of the vibrator 3. In addition, since the inner layer lens 4 is fixed to the portion of the housing 2 that is a node of vibration, the inner layer lens 4 does not attenuate the vibration of the vibrator 3 and also does not lower performance of removing foreign matters adhering to the outermost layer lens 1.

The fixing portion 5 that fixes the inner layer lens 4 to the housing 2 preferably has a mechanical quality factor Qm smaller than that of the housing 2. When the mechanical quality factor Qm of the fixing portion 5 is made smaller than that of the housing 2, the vibration of the vibrator 3 is less likely to be transmitted to the inner layer lens 4 through the fixing portion 5. Specifically, the fixing portion 5 is preferably made of resin.

The inner layer lens 4 has a configuration in which an inner layer lens barrel 4a holds a plurality of lenses. The inner layer lens barrel 4a is a holding portion of the inner layer lens 4. Since the plurality of lenses of the inner layer lens 4 is held by the inner layer lens barrel 4a in a state in which alignment adjustment is performed, alignment adjustment does not have to be performed for the individual lenses when the lenses are mounted in the optical device 100. However, in a case where alignment adjustment between the outermost layer lens 1 and the inner layer lens 4 is not performed when the outermost layer lens 1 and the inner layer lens 4 are mounted in the optical device 100, the image quality of images captured by an imaging element may be deteriorated. Note that even when the outermost layer lens 1 is not a lens but a light-transmissive body such as a protective cover, optical characteristics of the light-transmissive body such as refraction of light that has passed through the light-transmissive body affect images captured by the imaging element, and thus alignment adjustment between the light-transmissive body and the inner layer lens 4 is required.

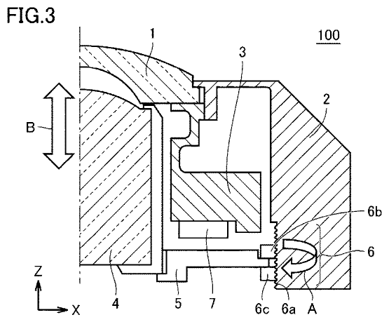

Therefore, in the optical device 100, the position adjustment portion 6 to perform alignment adjustment between the outermost layer lens 1 and the inner layer lens 4 is provided between the fixing portion 5 and the housing 2. FIG. 3 is a half sectional view for explaining the position adjustment portion 6 of the optical device 100 according to the first example embodiment. The one-dot chain line illustrated in FIG. 3 indicates a portion passing through a central axis of the optical device 100.

The position adjustment portion 6 illustrated in FIG. 3 includes a screw groove 6a provided on an inner wall surface of the housing 2 and two ring-shaped screws 6b and 6c corresponding to the screw groove 6a. The position adjustment portion 6 can fix the position of the inner layer lens 4 with respect to the housing 2 by holding an end portion of the fixing portion 5 between the two ring-shaped screws 6b and 6c. In addition, the position adjustment portion 6 can move the fixing portion 5 in the Z direction through turning of the two ring-shaped screws 6b and 6c in a direction of an arrow A so that the two ring-shaped screws 6b and 6c are moved along the screw groove 6a. Therefore, the position adjustment portion 6 can adjust a focal position by moving the inner layer lens 4 in a direction of an arrow B (the Z direction) with respect to the outermost layer lens 1. Since the position adjustment portion 6 is provided in a portion of the housing 2 where vibration by the vibrator 3 is reduced or prevented, positional displacement due to breakage or vibration of the position adjustment portion 6 can be reduced or prevented.

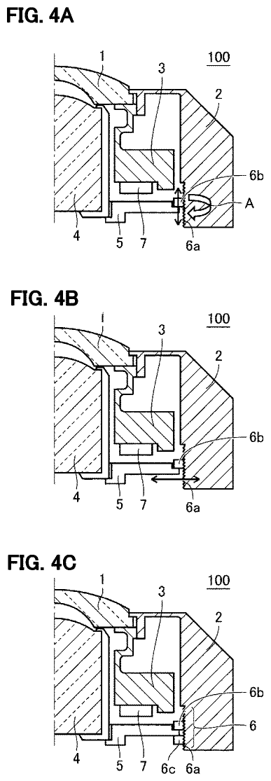

For the alignment adjustment between the outermost layer lens 1 and the inner layer lens 4, other than focal position adjustment in which the inner layer lens 4 is moved in the Z direction with respect to the outermost layer lens 1, optical axis adjustment in which the optical axis of the outermost layer lens 1 and the optical axis of the inner layer lens 4 are aligned is adopted. An alignment adjustment method including the optical axis adjustment will be described with reference to the figures. FIGS. 4A to 4C are schematic views for explaining an alignment adjustment method in the position adjustment portion 6 of the optical device 100 according to the first example embodiment.

First, as illustrated in FIG. 4A, the ring-shaped screw 6b is fit into the screw groove 6a and rotated to determine the position of the inner layer lens 4 in the Z direction. Next, an end portion of the fixing portion 5 fixed to the inner layer lens 4 is caused to abut the ring-shaped screw 6b whose position has been determined, as a result of which an angle θ (an elevation angle) defined by the optical axis of the inner layer lens 4 with respect to the optical axis of the outermost layer lens 1 can be adjusted by abutting position determination.

Moreover, as illustrated in FIG. 4B, in a state in which the end portion of the fixing portion 5 is caused to abut the ring-shaped screw 6b, the inner layer lens 4 and the fixing portion 5 are moved in the X and Y directions so that the optical axis of the inner layer lens 4 coincides with the optical axis of the outermost layer lens 1 to complete the optical axis adjustment.

Next, as illustrated in FIG. 4C, the ring-shaped screw 6c is fit into the screw groove 6a and rotated, and the end portion of the fixing portion 5 is held between the two ring-shaped screws 6b and 6c so that the position of the inner layer lens 4 with respect to the housing 2 is fixed. Note that in FIG. 4C, the end portion of the fixing portion 5 is held between the two ring-shaped screws 6b and 6c so that the position of the inner layer lens 4 with respect to the housing 2 is fixed, but the fixing method is not limited thereto.

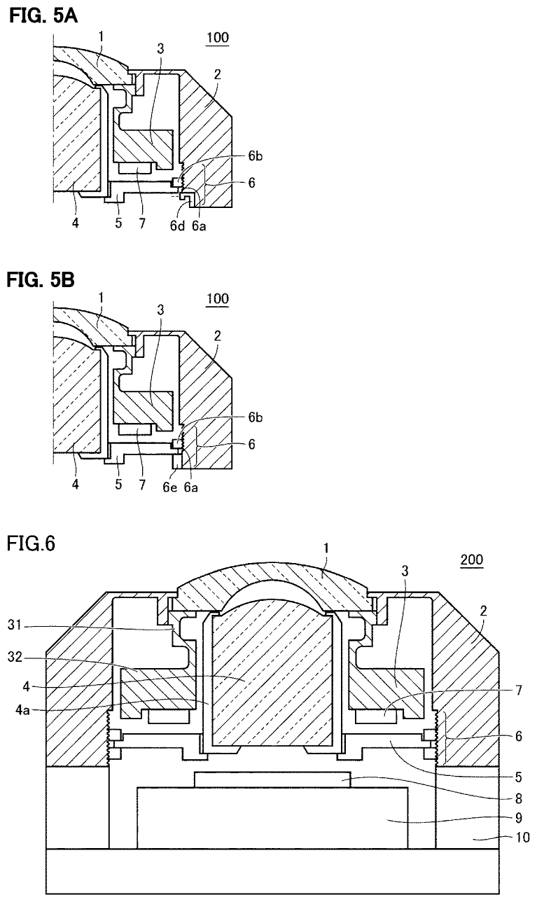

FIGS. 5A and 5B are schematic views for explaining a fixing method of the position adjustment portion 6 of the optical device 100 according to the first example embodiment. In FIG. 5A, instead of the ring-shaped screw 6c, a plate 6d made of metal or resin that can be swaged is fit into the screw groove 6a, and the end portion of the fixing portion 5 is held between the plate 6d that has been swaged and the ring-shaped screw 6b so as to be fixed. Note that the state of the plate 6d after being swaged is indicated by a broken line.

In addition, in FIG. 5B, instead of the ring-shaped screw 6c, the end portion of the fixing portion 5 is held between a block 6e that is fit into the screw groove 6a and the ring-shaped screw 6b and is fixed with an adhesive. It is needless to say that without providing the block 6e, the end portion of the fixing portion 5 may be fixed to the ring-shaped screw 6b by an adhesive only.

In FIGS. 4 and 5, the position of the inner layer lens 4 in the Z direction is adjusted using the ring-shaped screw 6b, but a screw portion may be directly provided at the end portion of the fixing portion 5. The position adjustment portion 6 has a screw portion at the end portion of the fixing portion 5 and changes the position with respect to the housing 2 provided with the screw groove 6a (a groove portion) corresponding to the screw portion so as to adjust the alignment of the inner layer lens 4 with respect to the outermost layer lens 1. As a result, the position adjustment portion 6 can adjust the position of the inner layer lens 4 in the Z direction without being provided with the ring-shaped screw 6b.

After the alignment adjustment between the outermost layer lens 1 and the inner layer lens 4 is performed, a case 10 including an imaging element 8 is attached to the optical device 100 so as to constitute an imaging unit 200. FIG. 6 is a sectional view of the imaging unit 200 including the optical device 100 according to the first example embodiment.

The imaging unit 200 includes the optical device 100 and the imaging element 8 disposed such that the outermost layer lens 1 and the inner layer lens 4 are provided in a visual field direction of the imaging element 8. The imaging element 8 is an image sensor s a charge coupled device (CCD) or a complementary metal-oxide-semiconductor (CMOS) sensor, for example, and is mounted on a circuit board 9. After alignment adjustment between the imaging element 8 mounted on the circuit board 9 and the inner layer lens 4 is performed, the circuit board 9 is fixed to the fixing portion 5 with an adhesive. Finally, the case 10 and the housing 2 are joined together and fixed with screws or an adhesive so that the imaging unit 200 is completed.

As described above, the optical device 100 according to the first example embodiment includes the outermost layer lens 1 (the light-transmissive body), the housing 2, the vibrator 3, the inner layer lens 4 (a first lens), the fixing portion 5, and the position adjustment portion 6. The outermost layer lens 1 allows light having a predetermined wavelength to pass therethrough. The housing 2 holds the outermost layer lens 1. The vibrator 3 vibrates the outermost layer lens 1 held by the housing 2. The inner layer lens 4 is provided at a position, in the housing 2, facing the outermost layer lens 1. The fixing portion 5 fixes the inner layer lens 4 to the housing 2. The position adjustment portion 6 is provided in the fixing portion 5 and adjusts alignment of the inner layer lens 4 with respect to the outermost layer lens 1. The fixing portion 5 is connected to a portion of the housing 2 that is a node of vibration by the vibrator 3.

As a result, since the optical device 100 according to the first example embodiment adjusts the alignment of the inner layer lens 4 with respect to the outermost layer lens 1 by the position adjustment portion 6 provided in the fixing portion 5 connected to the portion of the housing 2 that is a node of vibration by the vibrator 3, the optical device 100 can remove foreign matters adhering to the outermost layer lens 1 that covers the outer portion of the optical device 100 and improve the image quality of images captured by the imaging element 8.

The light-transmissive body is preferably the outermost layer lens 1 (a second lens). The light-transmissive body may be a protective cover, which is not a lens. The vibrator 3 is preferably provided with the piezoelectric element 7 at least on one surface. In FIG. 1, the piezoelectric element 7 having a hollow cylindrical shape is provided on the bottom surface of the vibrator 3, but in addition to the above-described piezoelectric element 7, a piezoelectric element may be provided on another surface, and alternatively, a plurality of the piezoelectric elements 7 having a rectangular or substantially rectangular shape may be provided concentrically on the bottom surface of the vibrator 3.

The fixing portion 5 preferably has the mechanical quality factor Qm smaller than that of the housing 2. In addition, the fixing portion 5 is preferably made of resin. As a result, the vibration of the vibrator 3 is less likely to be transmitted to the inner layer lens 4 through the fixing portion 5.

The position adjustment portion 6 is preferably provided at the end portion of the fixing portion 5 connected to the housing 2. In FIG. 1, the two ring-shaped screws 6b and 6c holding the end portion of the fixing portion 5 therebetween constitute the position adjustment portion 6. Since the fixing portion 5 is connected to a portion of the housing 2 that is a node of vibration of the vibrator 3, when the position adjustment portion 6 is provided at the end portion of the fixing portion 5, the position adjustment portion 6 is not affected by the vibration by the vibrator 3, alignment adjustment with high accuracy is possible, and the image quality of images captured by the imaging element 8 is improved.

The imaging unit 200 includes the optical device 100 and the imaging element 8 disposed such that the outermost layer lens 1 and the inner layer lens 4 are provided in the visual field direction of the imaging element 8. As a result, in the imaging unit 200, alignment adjustment with high accuracy is possible in the optical device 100, and the image quality of images captured by the imaging element 8 is improved.

### Second Example Embodiment

In the optical device 100 according to the first example embodiment, a configuration in which the position adjustment portion 6 is provided at the end portion of the fixing portion 5 connected to the housing 2 has been described. However, as long as the position adjustment portion is provided in the fixing portion connected to a portion of the housing that is a node of vibration by the vibrator, the position adjustment portion is less likely to be affected by the vibration by the vibrator. Therefore, in an optical device according to a second example embodiment, a configuration in which the position adjustment portion is provided at an end portion of the fixing portion connected to the inner layer lens (the first lens) will be described.

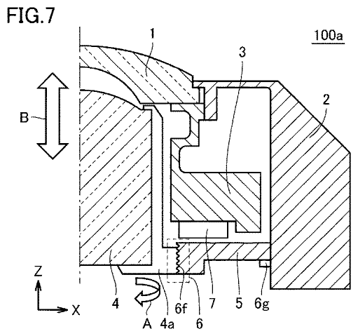

FIG. 7 is a half sectional view of an optical device 100a according to the second example embodiment. Note that in the optical device 100a illustrated in FIG. 7, similar structures to those of the optical device 100 according to the first example embodiment are denoted by the same reference numerals, and description thereof will not be repeated.

In the optical device 100a according to the second example embodiment, as illustrated in FIG. 7, the position adjustment portion 6 is a screw portion 6f provided at an end portion of the fixing portion 5 connected to the inner layer lens 4. A groove portion corresponding to the screw portion 6f is provided in the inner layer lens barrel 4a. When the inner layer lens barrel 4a is turned in a direction of the arrow A, the inner layer lens barrel 4a is moved along the screw portion 6f, so that the position adjustment portion 6 can move the inner layer lens 4 in the Z direction. Therefore, the position adjustment portion 6 can adjust the focal position by moving the inner layer lens 4 in a direction of the arrow B (the Z direction) with respect to the outermost layer lens 1.

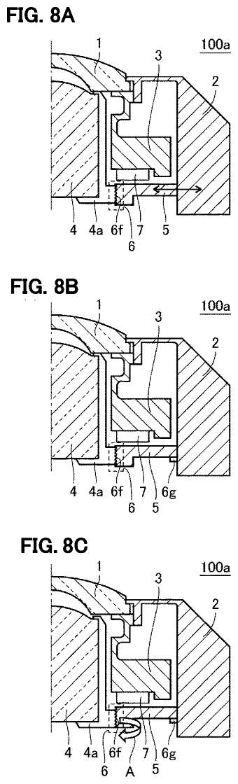

An alignment adjustment method in the optical device 100a according to the second example embodiment will be described with reference to the figures. FIGS. 8A to 8C are schematic views for explaining the alignment adjustment method in the position adjustment portion 6 of the optical device 100a according to the second example embodiment.

First, as illustrated in FIG. 8A, in a state in which the fixing portion 5 is not fixed to the housing 2, a planar portion of the inner layer lens barrel 4a is caused to abut a planar portion of the outermost layer lens 1, as a result of which the angle θ (the elevation angle) defined by the optical axis of the inner layer lens 4 with respect to the optical axis of the outermost layer lens 1 can be adjusted by abutting position determination. Moreover, in a state in which the planar portion of the inner layer lens barrel 4a is caused to abut the planar portion of the outermost layer lens 1, the inner layer lens 4 and the fixing portion 5 are moved in the X and Y directions so that the optical axis of the inner layer lens 4 coincides with the optical axis of the outermost layer lens 1 to complete the optical axis adjustment.

Next, as illustrated in FIG. 8B, at a position of the inner layer lens 4 at which the alignment adjustment has been performed with respect to the outermost layer lens 1, an end portion of the fixing portion 5 is fixed to the housing 2 with an adhesive. Note that in the FIG. 8B, the position of the inner layer lens 4 with respect to the housing 2 is fixed through fixing of the end portion of the fixing portion 5 to the housing 2 with an adhesive, but the fixing method is not limited thereto.

Moreover, as illustrated in FIG. 8C, the inner layer lens barrel 4a is turned in the direction of the arrow A with respect to the screw portion 6f so that the position of the inner layer lens 4 in the Z direction is determined. After the alignment adjustment between the outermost layer lens 1 and the inner layer lens 4 is performed, the case 10 including the imaging element 8 illustrated in FIG. 6 is attached to the optical device 100a so as to constitute the imaging unit 200.

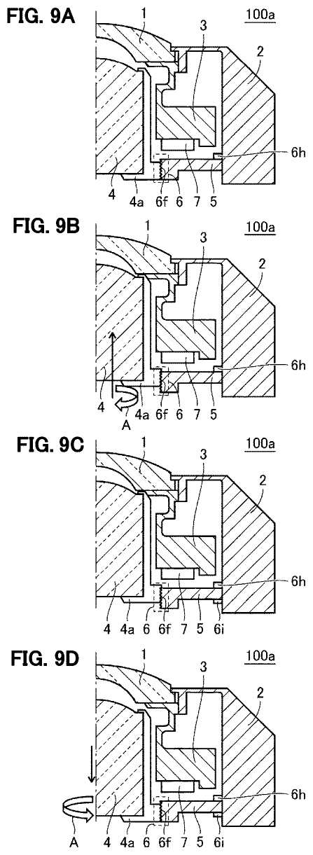

Next, another alignment adjustment method in the optical device 100a according to the second example embodiment will be described with reference to the figures. FIGS. 9A to 9D are schematic views for explaining the other alignment adjustment method in the position adjustment portion 6 of the optical device 100a according to the second example embodiment.

First, as illustrated in FIG. 9A, the housing 2 is provided with a projecting portion 6h to join the housing 2 to the fixing portion 5. The projecting portion 6h is used to adjust the angle θ (the elevation angle) defined by the optical axis of the inner layer lens 4 with respect to the optical axis of the outermost layer lens 1 by abutting position determination. That is, in a state in which the fixing portion 5 is not fixed to the housing 2, an end portion of the fixing portion 5 is caused to abut the projecting portion 6h, as a result of which the angle θ (the elevation angle) defined by the optical axis of the inner layer lens 4 with respect to the optical axis of the outermost layer lens 1 can be adjusted by abutting position determination.

Moreover, as illustrated in FIG. 9B, the inner layer lens barrel 4a is turned in the direction of the arrow A with respect to the screw portion 6f to bring the inner layer lens barrel 4a close to the vibrator 3 so that a tapered portion of the inner layer lens barrel 4a abuts a tapered portion of the vibrator 3. When the tapered portion of the inner layer lens barrel 4a is caused to abut the tapered portion of the vibrator 3, the inner layer lens 4 and the fixing portion 5 are moved in the X and Y directions so that the optical axis of the inner layer lens 4 coincides with the optical axis of the outermost layer lens 1 to complete the optical axis adjustment.

Moreover, as illustrated in FIG. 9C, after the optical axis adjustment for coinciding the optical axis of the inner layer lens 4 with the optical axis of the outermost layer lens 1 is completed, the end portion of the fixing portion 5 is held between a block 6i and the projecting portion 6h so that the position of the inner layer lens 4 is fixed. The method of fixing the position of the inner layer lens 4 is not limited to the method using the block 6i, and the position of the inner layer lens 4 may be fixed by a plate that can be swaged or an adhesive only.

Next, as illustrated in FIG. 9D, the inner layer lens barrel 4a is turned in the direction of the arrow A with respect to the screw portion 6f so that the position of the inner layer lens 4 in the Z direction is determined. As a result, the position adjustment portion 6 can adjust the focal position by moving the inner layer lens 4 in the Z direction with respect to the outermost layer lens 1.

In FIGS. 8 and 9, alignment adjustment is performed by abutting position determination in which the planar portion of the inner layer lens barrel 4a is caused to abut the planar portion of the outermost layer lens 1, or the tapered portion of the inner layer lens barrel 4a is caused to abut the tapered portion of the vibrator 3. Here, structures that can be used for abutting position determination will be summarized and described.

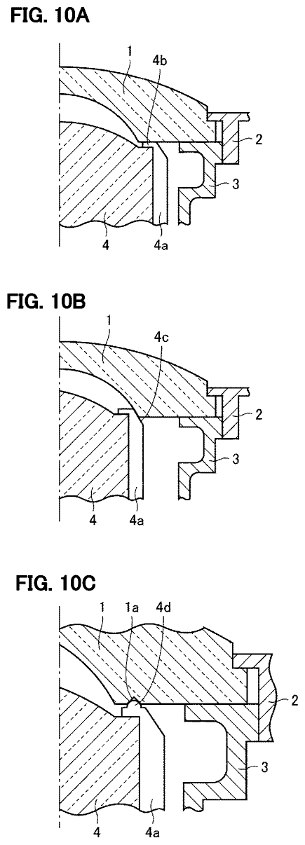

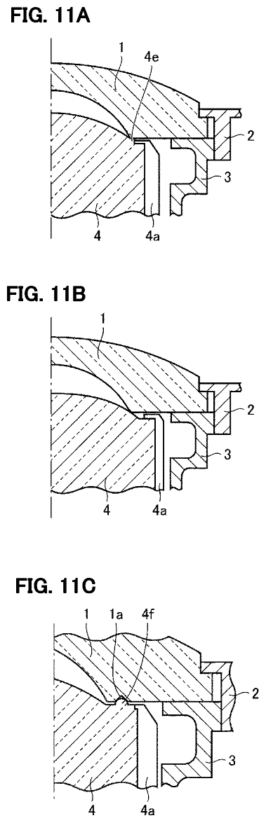

First, FIGS. 10A to 10C are views for explaining a configuration using the outermost layer lens 1 and a holding portion (the inner layer lens barrel 4a) of the inner layer lens 4 for abutting position determination in the optical device. FIG. 10A illustrates that when a planar portion of the outermost layer lens 1 is caused to abut a planar portion 4b of the inner layer lens barrel 4a, alignment adjustment (mainly the angle θ (the elevation angle)) of the inner layer lens 4 with respect to the outermost layer lens 1 can be performed by abutting position determination.

FIG. 10B illustrates that when a tapered portion of the outermost layer lens 1 is caused to abut a tapered portion 4c of the inner layer lens barrel 4a, alignment adjustment (mainly in the X and Y directions) of the inner layer lens 4 with respect to the outermost layer lens 1 can be performed by abutting position determination. FIG. 10C illustrates that when a recess 1a of the outermost layer lens 1 is caused to abut a projection 4d of the inner layer lens barrel 4a, alignment adjustment (mainly in the X and Y directions) of the inner layer lens 4 with respect to the outermost layer lens 1 can be performed by abutting position determination. Note that the shapes defined by the outermost layer lens 1 and the inner layer lens barrel 4a are not limited to the recess 1a and the projection 4d, and a recess and a projection may be provided in the inner layer lens barrel 4a and the outermost layer lens 1, respectively.

Next, FIGS. 11A to 11C are views for explaining a configuration using the outermost layer lens 1 and the inner layer lens 4 for abutting position determination in the optical device. FIG. 11A illustrates that when a planar portion of the outermost layer lens 1 is caused to abut a planar portion 4e of the inner layer lens 4, alignment adjustment (mainly the angle θ (the elevation angle)) of the inner layer lens 4 with respect to the outermost layer lens 1 can be performed by abutting position determination.

FIG. 11B illustrates that when a tapered portion of the outermost layer lens 1 is caused to abut a tapered portion of the inner layer lens 4, alignment adjustment (mainly in the X and Y directions) of the inner layer lens 4 with respect to the outermost layer lens 1 can be performed by abutting position determination. FIG. 11C illustrates that when the recess 1a of the outermost layer lens 1 is caused to abut a projection 4f of the inner layer lens 4, alignment adjustment (mainly in the X and Y directions) of the inner layer lens 4 with respect to the outermost layer lens 1 can be performed by abutting position determination. Note that the shapes defined by the outermost layer lens 1 and the inner layer lens 4 are not limited to the recess 1a and the projection 4f, and a recess and a projection may be provided in the inner layer lens 4 and the outermost layer lens 1, respectively.

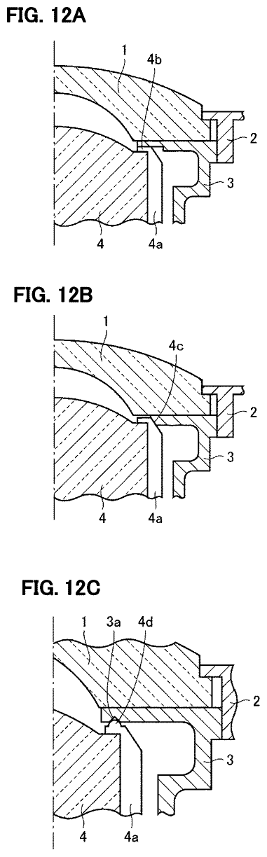

Next, FIGS. 12A to 12C are views for explaining a configuration using the vibrator 3 and the holding portion (the inner layer lens barrel 4a) of the inner layer lens 4 for abutting position determination in the optical device. FIG. 12A illustrates that when a planar portion of the vibrator 3 is caused to abut the planar portion 4b of the inner layer lens barrel 4a, alignment adjustment (mainly the angle θ (the elevation angle)) of the inner layer lens 4 with respect to the outermost layer lens 1 can be performed by abutting position determination.

FIG. 12B illustrates that when a tapered portion of the vibrator 3 is caused to abut the tapered portion 4c of the inner layer lens barrel 4a, alignment adjustment (mainly in the X and Y directions) of the inner layer lens 4 with respect to the outermost layer lens 1 can be performed by abutting position determination. FIG. 12C illustrates that when a recess 3a of the vibrator 3 is caused to abut the projection 4d of the inner layer lens barrel 4a, alignment adjustment (mainly in the X and Y directions) of the inner layer lens 4 with respect to the outermost layer lens 1 can be performed by abutting position determination. Note that the shapes defined by the vibrator 3 and the inner layer lens barrel 4a are not limited to the recess 3a and the projection 4d, and a recess and a projection may be provided in the inner layer lens barrel 4a and the vibrator 3, respectively.

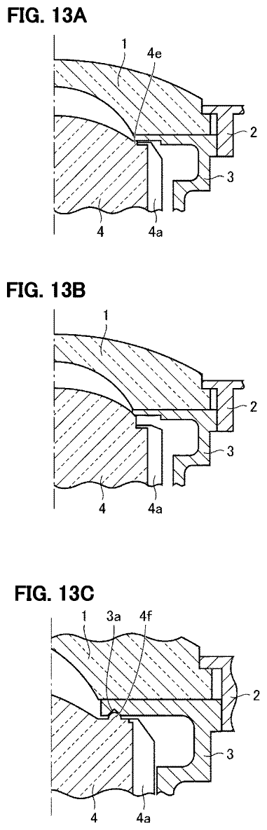

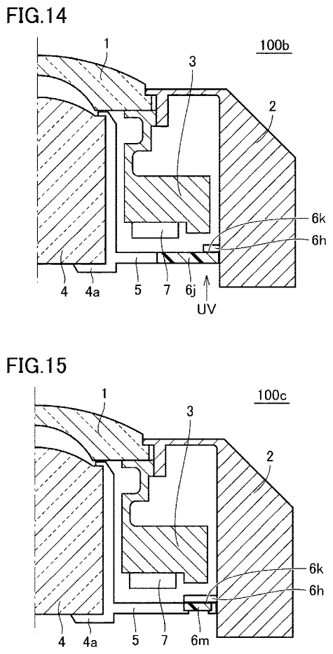

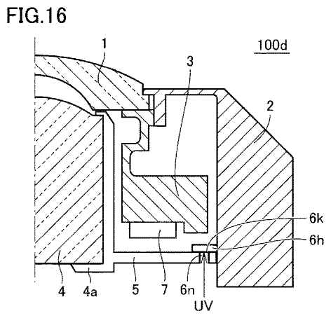

Finally, FIGS. 13A to 13C are views for explaining a configuration using the vibrator 3 and the inner layer lens 4 for abutting position determination in the optical device. FIG. 13A illustrates that when a planar portion of the vibrator 3 is caused to abut the planar portion 4e of the inner layer lens 4, alignment adjustment (mainly the angle θ (the elevation angle)) of the inner layer lens 4 with respect to the outermost layer lens 1 can be performed by abutting position determination.

FIG. 13B illustrates that when a tapered portion of the vibrator 3 is caused to abut a tapered portion of the inner layer lens 4, alignment adjustment (mainly in the X and Y directions) of the inner layer lens 4 with respect to the outermost layer lens 1 can be performed by abutting position determination. FIG. 13C illustrates that when the recess 3a of the vibrator 3 is caused to abut the projection 4f of the inner layer lens 4, alignment adjustment (mainly in the X and Y directions) of the inner layer lens 4 with respect to the outermost layer lens 1 can be performed by abutting position determination. Note that the shapes defined by the vibrator 3 and the inner layer lens 4 are not limited to the recess 3a and the projection 4f, and a recess and a projection may be provided in the inner layer lens 4 and the vibrator 3, respectively.

The configurations for abutting position determination illustrated in FIGS. 10 to 12 can be used not only for the optical device 100a according to the second example embodiment, but also for optical devices according to other example embodiments in the same manner.

As described above, in the optical device 100a according to the second example embodiment, the position adjustment portion 6 is provided at the end portion of the fixing portion 5 connected to the inner layer lens 4. In addition, the position adjustment portion 6 includes the screw portion 6f at the end portion of the fixing portion 5 and changes the position with respect to the inner layer lens barrel 4a provided with the groove portion corresponding to the screw portion 6f so as to adjust the alignment of the inner layer lens 4 with respect to the outermost layer lens 1. As a result, since the optical device 100a according to the second example embodiment adjusts the alignment of the inner layer lens 4 with respect to the outermost layer lens 1 by the position adjustment portion 6 provided in the fixing portion 5 connected to a portion of the housing 2 that is a node of vibration by the vibrator 3, the optical device 100a can remove foreign matters adhering to the outermost layer lens 1 that covers the outer portion of the optical device 100a and improve the image quality of images captured by the imaging element. Note that the screw portion 6f provided at the end portion of the fixing portion 5 in the second example embodiment may be provided in optical devices according to other example embodiments.

The outermost layer lens 1 or the vibrator 3 preferably has a planar portion (a first planar portion), the inner layer lens 4 or the inner layer lens barrel 4a preferably includes the planar portion 4e or 4b (a second planar portion), respectively, and the planar portion (the first planar portion) and the planar portion 4e or 4b (the second planar portion) are preferably capable of abutting on each other. The outermost layer lens 1 or the vibrator 3 preferably has a tapered portion (a first tapered portion), the inner layer lens 4 or the inner layer lens barrel 4a preferably has the tapered portion 4c (a second tapered portion), and the tapered portion (the first tapered portion) and the tapered portion 4c (the second tapered portion) are preferably capable of abutting on each other. The outermost layer lens 1 or the vibrator 3 preferably has the recess 1a or 3a (a first fitting portion), respectively, the inner layer lens 4 or the inner layer lens barrel 4a preferably has the projection 4f or 4d (a second fitting portion), respectively, and the recess 1a or 3a (the first fitting portion) and the projection 4f or 4d (the second fitting portion) are preferably capable of abutting on each other. As a result, the alignment adjustment of the inner layer lens 4 with respect to the outermost layer lens 1 can be performed by abutting position determination.

### Third Example Embodiment

In the first example embodiment, it has been described that after alignment adjustment is performed, the end portion of the fixing portion 5 may be fixed to the housing 2 with an adhesive. In a third example embodiment, a configuration in which after alignment adjustment is performed, the end portion of the fixing portion 5 is fixed to the housing 2 with an adhesive will be described. FIG. 14 is a half sectional view of an optical device 100b according to the third example embodiment. Note that in the optical device 100b illustrated in FIG. 14, similar structures to those of the optical device 100 according to the first example embodiment are denoted by the same reference numerals, and description thereof will not be repeated.

As illustrated in FIG. 14, the optical device 100b is provided with the projecting portion 6h to join the housing 2 to the fixing portion 5. The projecting portion 6h and the end portion of the fixing portion 5 are adhered with an ultraviolet curable adhesive 6k, but in order to cure the adhesive 6k, after the projecting portion 6h and the end portion of the fixing portion 5 are bonded together, ultraviolet (UV) light needs to be irradiated. However, when the projecting portion 6h and the fixing portion 5 do not allow ultraviolet light to pass therethrough, even after ultraviolet light is irradiated after the projecting portion 6h and the end portion of the fixing portion 5 are bonded together, there is a possibility that the adhesive 6k provided between the projecting portion 6h and the end portion of the fixing portion 5 is not cured.

Therefore, in the optical device 100b, the end portion of the fixing portion 5 has a structure 6j that allows ultraviolet light to pass therethrough. The structure 6j is capable of allowing ultraviolet light to pass therethrough to cure the ultraviolet curable adhesive 6k provided between the structure 6j and the projecting portion 6h located at a position facing the structure 6j after the alignment of the inner layer lens 4 with respect to the outermost layer lens 1 is adjusted. Note that not only the end portion of the fixing portion 5, but also the fixing portion 5 itself may be the structure 6j that allows ultraviolet light to pass therethrough.

In the optical device 100b illustrated in FIG. 14, the structure 6j that allows ultraviolet light to pass therethrough is provided at the end portion of the fixing portion 5, but a configuration in which at least one window portion that allows ultraviolet light to pass therethrough is provided at the end portion of the fixing portion 5 may be adopted. FIG. 15 is a half sectional view of an optical device 100c according to a first modification of the third example embodiment. Note that in the optical device 100c illustrated in FIG. 15, similar structures to those of the optical device 100 according to the first example embodiment are denoted by the same reference numerals, and description thereof will not be repeated.

In the optical device 100c, the end portion of the fixing portion 5 includes at least one window portion 6m that allows ultraviolet light to pass therethrough. The window portion 6m is capable of allowing ultraviolet light to pass therethrough to cure the ultraviolet curable adhesive 6k provided between the window portion 6m and the projecting portion 6h located at a position facing the window portion 6m after the alignment of the inner layer lens 4 with respect to the outermost layer lens 1 is adjusted.

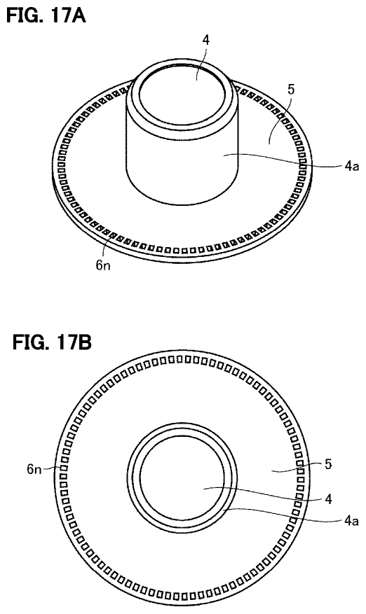

Moreover, instead of the configuration in which the structure 6j or the window portion 6m that allows ultraviolet light to pass therethrough is provided at the end portion of the fixing portion 5, a configuration in which a slit is provided may be adopted. FIG. 16 is a half sectional view of an optical device 100d according to a second modification of the third example embodiment. FIGS. 17A and 17B are schematic views of the inner layer lens 4 and the fixing portion 5 according to the second modification. Note that in the optical device 100d illustrated in FIGS. 16 and 17, similar structures to those of the optical device 100 according to the first example embodiment are denoted by the same reference numerals, and description thereof will not be repeated.

In the optical device 100d, the end portion of the fixing portion 5 has at least one slit 6n. As illustrated in FIGS. 17A and 17B, a plurality of the slits 6n is provided so as to surround the outer periphery of the fixing portion 5. The slits 6n are capable of allowing ultraviolet light to pass therethrough to cure the ultraviolet curable adhesive 6k provided between the slits 6n and the projecting portion 6h located at a position facing the slits 6n after the alignment of the inner layer lens 4 with respect to the outermost layer lens 1 is adjusted.

As described above, in the optical devices 100b and 100c according to the third example embodiment, the fixing portion 5 has the structure 6j or at least one window portion 6m, at the end portion thereof, that allows ultraviolet light to pass therethrough, and the structure 6j or the window portion 6m is capable of allowing ultraviolet light to pass therethrough to cure the ultraviolet curable adhesive 6k provided between the structure 6j or the window portion 6m and the projecting portion 6h located at a position facing the structure 6j or the window portion 6m after the alignment of the inner layer lens 4 with respect to the outermost layer lens 1 is adjusted. As a result, in the optical devices 100b and 100c, the end portion of the fixing portion 5 can be fixed to the housing 2 at a position of the end portion of the fixing portion 5 after alignment adjustment is performed.

In the optical device 100d according to the third example embodiment, the fixing portion 5 has at least one slit 6n in the end portion, and since the slit 6n is capable of allowing ultraviolet light to pass therethrough to cure the ultraviolet curable adhesive 6k provided between the slit 6n and the projecting portion 6h located at a position facing the slit 6n after the alignment of the inner layer lens 4 with respect to the outermost layer lens 1 is adjusted. As a result, in the optical device 100d, the end portion of the fixing portion 5 can be fixed to the housing 2 at a position of the end portion of the fixing portion 5 after alignment adjustment is performed.

### Fourth Example Embodiment

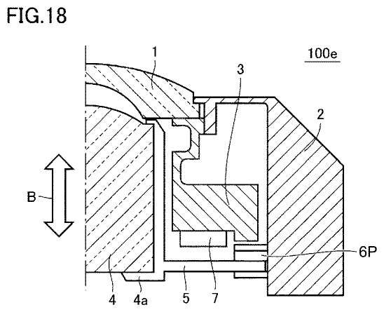

In the first example embodiment, it has been described that after alignment adjustment is performed, the end portion of the fixing portion 5 is fixed. In a fourth example embodiment, a structure that actively performs alignment adjustment with respect to fluctuation of alignment is adopted as a position adjustment portion. FIG. 18 is a half sectional view of an optical device according to the fourth example embodiment. Note that in an optical device 100e illustrated in FIG. 18, similar structures to those of the optical device 100 according to the first example embodiment are denoted by the same reference numerals, and description thereof will not be repeated.

In the optical device 100e, as a position adjustment portion to perform alignment adjustment between the outermost layer lens 1 and the inner layer lens 4, an actuator 6P is provided at the end portion of the fixing portion 5 connected to the housing 2. The actuator 6P includes a piezoelectric body (single layer, multilayer), a motor (voice coil motor), or the like. The actuator 6P actively adjusts the alignment of the inner layer lens 4 with respect to the outermost layer lens 1 based on a control signal from a control circuit (not illustrated) that detects fluctuation of alignment from an image captured by the imaging element 8 or output of a sensor provided in the inner layer lens 4 or the like. The actuator 6P may be provided at the end portion of the fixing portion 5 connected to the inner layer lens 4.

As described above, in the optical device 100e according to the fourth example embodiment, the position adjustment portion is the actuator 6P provided at an end portion of the fixing portion 5. As a result, in the optical device 100e, alignment adjustment can be actively performed with respect to fluctuation of the alignment of the inner layer lens 4 with respect to the outermost layer lens 1, and the image quality of images captured by the imaging element can be improved.

### Other Modifications

The imaging unit 200 according to the above-described example embodiments may include a camera, a light detection and ranging (LiDAR), a radio detecting and ranging (Radar), or the like. In addition, a plurality of imaging units may be arranged in sequence.

The imaging unit 200 according to the above-described example embodiments is not limited to an imaging unit provided in a vehicle, includes an optical device and an imaging element disposed such that a light-transmissive body is provided in a visual field direction of the imaging element, and can be applied in a similar manner to any type of imaging unit in which foreign matters adhering to the light-transmissive body need to be removed.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An optical device comprising:
a light-transmissive body to allow light having a predetermined wavelength to pass therethrough;
a housing to hold the light-transmissive body;
a vibrator to vibrate the light-transmissive body held by the housing;
a first lens positioned in the housing to face the light-transmissive body;
a fixing portion to fix the first lens to the housing; and
a position adjustment portion that is provided in the fixing portion to adjust alignment of the first lens with respect to the light-transmissive body; wherein
the fixing portion is connected to a portion of the housing that is a node of vibration by the vibrator.

2. The optical device according to claim 1, wherein the light-transmissive body is a second lens.

3. The optical device according to claim 1, wherein the vibrator includes at least one surface that is provided with a piezoelectric element.

4. The optical device according to claim 1, wherein the fixing portion has a mechanical quality factor Qm smaller than a mechanical quality factor Qm of the housing.

5. The optical device according to claim 4, wherein the fixing portion is made of resin.

6. The optical device according to claim 1, wherein the position adjustment portion is provided at an end portion of the fixing portion connected to the housing.

7. The optical device according to claim 1, wherein the position adjustment portion is provided at an end portion of the fixing portion connected to the first lens.

8. The optical device according to claim 6, wherein the position adjustment portion includes a screw portion at an end portion of the fixing portion to change a position with respect to a structure including a groove portion corresponding to the screw portion to adjust alignment of the first lens with respect to the light-transmissive body.

9. The optical device according to claim 6, wherein the fixing portion includes, at an end portion thereof, a structure or at least one window portion to allow ultraviolet light to pass therethrough; and
the structure or the window portion is capable of allowing ultraviolet light to pass therethrough to cure an ultraviolet curable adhesive provided between the structure or the window portion and another structure located at a position facing the structure or the window portion after alignment of the first lens with respect to the light-transmissive body is adjusted.

10. The optical device according to claim 6, wherein the fixing portion includes at least one slit in an end portion thereof; and
the slit is capable of allowing ultraviolet light to pass therethrough to cure an ultraviolet curable adhesive provided between the slit and a structure located at a position facing the slit after alignment of the first lens with respect to the light-transmissive body is adjusted.

11. The optical device according to claim 6, wherein the position adjustment portion includes an actuator provided at an end portion of the fixing portion.

12. The optical device according to claim 1, wherein the light-transmissive body or the vibrator includes a first planar portion;
the first lens or a holding portion of the first lens includes a second planar portion; and
the first planar portion and the second planar portion are capable of abutting each other.

13. The optical device according to claim 1, wherein the light-transmissive body or the vibrator includes a first tapered portion;
the first lens or a holding portion of the first lens includes a second tapered portion; and
the first tapered portion and the second tapered portion are capable of abutting each other.

14. The optical device according to claim 1, wherein the light-transmissive body or the vibrator includes a first fitting portion;
the first lens or a holding portion of the first lens includes a second fitting portion; and
the first fitting portion and the second fitting portion are capable of fitting to each other.

15. An imaging unit comprising:
the optical device according to claim 1; and
an imager positioned such that the light-transmissive body and the first lens are provided in a visual field direction of the imaging unit.

16. The imaging unit according to claim 15, wherein the light-transmissive body is a second lens.

17. The imaging unit according to claim 15, wherein the vibrator includes at least one surface that is provided with a piezoelectric element.

18. The imaging unit according to claim 15, wherein the fixing portion has a mechanical quality factor Qm smaller than a mechanical quality factor Qm of the housing.

19. The imaging unit according to claim 18, wherein the fixing portion is made of resin.

20. The imaging unit according to claim 15, wherein the position adjustment portion is provided at an end portion of the fixing portion connected to the housing.
